(19) United States
(12) Patent Application Publication
(10) Pub. No.: US 2026/0206520 A1
(43) Pub. Date: Jul. 16, 2026

(54) Mask Cleaning Device And Mask Cleaning Method

(71) Applicant: Samsung Display Co., Ltd., Yongin-si (KR)

(72) Inventors: DEOKCHAN YOON, Yongin-si (KR); SOOBONG KIM, Yongin-si (KR); NARAE PARK, Yongin-si (KR); HEEYEON YOO, Yongin-si (KR)

(73) Assignee: Samsung Display Co., Ltd., Yongin-si (KR)

(21) Appl. No.: 19/444,335

(22) Filed: Jan. 9, 2026

(30) Foreign Application Priority Data
Jan. 13, 2025 (KR) 10-2025-0004533

(51) Int. Cl. H10P 72/00; C23C 14/04

(52) U.S. Cl. CPC H10P 72/0414; C23C 14/042

(57) ABSTRACT

A mask cleaning device includes a chamber providing a cleaning space for a mask, a heating unit in which the mask is arranged and which is configured to adjust a heating temperature value of a main body in which the mask is arranged, a cleaning gas supply unit configured to supply a cleaning gas to the mask, and a control unit configured to control the heating unit and the cleaning gas supply unit, in which the control unit is further configured to control the heating unit such that the heating temperature value is equal to or greater than a first process temperature value and control the cleaning gas supply unit to supply the cleaning gas to the mask during a cleaning time.

### CROSS-REFERENCE TO RELATED APPLICATION

This application claims priority under 35 U.S.C. §119 to Korean Patent Application No. 10-2025-0004533, filed on January 13, 2025, in the Korean Intellectual Property Office, the disclosure of which is incorporated by reference herein in its entirety.

### TECHNICAL FIELD

The disclosure relates to a mask cleaning device and a mask cleaning method.

### BACKGROUND

A mask is a key component for forming precise patterns on a substrate. In an electronic component manufacturing process, a precisely patterned mask may come into very close proximity to or contact with a substrate to transfer the pattern shape on the mask and thus pattern the substrate.

To reuse the mask, the mask needs to be cleaned. Specifically, to implement precise patterns by reusing the mask, the mask needs to be thoroughly cleaned to ensure that no organic material remains on the mask.

The mask may be cleaned using either a wet cleaning method or a dry cleaning method.

### SUMMARY

The disclosure provides a mask cleaning device and a mask cleaning method to improve the cleaning efficiency of the mask.

According to an aspect of the disclosure, a mask cleaning device includes a chamber providing a cleaning space for a mask, a heating unit in which the mask is arranged and which is configured to adjust a heating temperature value of a main body in which the mask is arranged, a cleaning gas supply unit configured to supply a cleaning gas to the mask, and a control unit configured to control the heating unit and the cleaning gas supply unit, in which the control unit is further configured to control the heating unit such that the heating temperature value is equal to or greater than a first process temperature value and control the cleaning gas supply unit to supply the cleaning gas to the mask during a cleaning time.

In an aspect, the control unit may be further configured to control the heating unit such that the heating temperature value is equal to or greater than a second process temperature value during a pre-treatment time before supplying the cleaning gas to the mask.

In an aspect, the first process temperature value may be greater than the second process temperature value.

In an aspect, the pre-treatment time may be less than the cleaning time.

In an aspect, the mask cleaning device may further include a gas supply unit configured to supply an inert gas into the chamber.

In an aspect, the cleaning gas supply unit may include a cleaning gas generation unit including an inner space spatially separated from the chamber and configured to generate the cleaning gas using a source gas and a spray unit fluidly connected to the cleaning gas generation unit and configured to spray the cleaning gas generated in the cleaning gas generation unit to the mask.

In an aspect, the spray unit may be arranged to face a surface of the heating unit on which the mask is arranged.

In an aspect, the cleaning gas supply unit may be further configured to supply a cleaning gas including hydrogen radicals to the mask.

In an aspect, the cleaning gas supply unit may be further configured to generate the cleaning gas including the hydrogen radicals by using a gas combining a hydrogen gas with water vapor.

In an aspect, the heating unit may include an elevating unit configured to arrange the mask apart from the main body.

In an aspect, the control unit may be further configured to control the elevating unit such that the mask is arranged apart from the main body after an elapse of a first time, and the mask is returned to the main body after an elapse of a second time.

In an aspect, the mask cleaning device may further include a pump configured to discharge fluid inside the chamber to outside.

In an aspect, the mask cleaning device may further include a baffle arranged between the heating unit and the cleaning gas supply unit and configured to adjust flow of the cleaning gas supplied from the cleaning gas supply unit.

According to another aspect of the disclosure, a mask cleaning method includes generating a cleaning gas using a source gas, adjusting the heating temperature value such that a heating temperature value of a main body on which a mask is arranged has a first process temperature value, and supplying the cleaning gas to the mask arranged inside the chamber during a cleaning time to clean the mask.

In an aspect the mask cleaning method may further include pre-treating the mask such that the mask has a temperature value corresponding to a second process temperature value during a pre-treatment time.

In an aspect, the first process temperature value may be greater than the second process temperature value.

In an aspect, the pre-treatment time may be less than the cleaning time.

In an aspect, the generating of the cleaning gas may include generating the cleaning gas including hydrogen radicals.

In an aspect, the cleaning of the mask may include arranging the mask apart from the main body after an elapse of a first time while supplying the cleaning gas and returning the mask onto the main body after an elapse of a second time while supplying the cleaning gas.

In an aspect, the mask cleaning method may further include discharging fluid inside the chamber to outside.

According to another aspect of the disclosure, an electronic device manufacturing system includes a cleaning device configured to remove organic material on a used mask, a deposition device configured to manufacture a display panel using the mask from which the organic material is removed, and an assembly device configured to assemble an electronic device using the display panel, in which the cleaning device includes a chamber providing a cleaning space for the mask, a heating unit in which the mask is arranged and which is configured to adjust a heating temperature value of a main body in which the mask is arranged, a cleaning gas supply unit configured to supply a cleaning gas to the mask, and a control unit configured to control the heating unit and the cleaning gas supply unit, in which the control unit is further configured to control the heating unit such that the heating temperature value is equal to or greater than a first process temperature value and control the cleaning gas supply unit to supply the cleaning gas to the mask during a cleaning time.

### BRIEF DESCRIPTION OF THE DRAWINGS

FIG. 1 schematically shows a mask cleaning device according to an aspect of the disclosure;

FIG. 2 shows a mask cleaning device according to another aspect of the disclosure;

FIG. 3 is a view enlarging a portion A of FIG. 1;

FIG. 4 is a view showing some components of FIG. 3 in operation;

FIG. 5 is an experimental result graph showing the amount of organic material remaining on a mask after cleaning with respect to a heating temperature;

FIG. 6 is an experimental result graph showing the amount of organic material remaining on a mask after cleaning with respect to a pre-treatment time;

FIG. 7 is a flowchart showing a mask cleaning method according to an aspect of the disclosure;

FIG. 8 is a flowchart showing in detail some operations of FIG. 7;

FIG. 9 is a flowchart showing a mask cleaning method according to another aspect of the disclosure; and

FIG. 10 is a flowchart showing a mask cleaning method according to another aspect of the disclosure.

### DETAILED DESCRIPTION

The disclosure may have various modifications thereto and various aspects, and thus particular aspects will be illustrated in the drawings and described in detail in the detailed description. Effects and features of the disclosure, and methods for achieving them will become clear with reference to the aspects described later in detail together with the drawings. However, the disclosure is not limited to the aspects disclosed below and may be implemented in various forms.

In the following aspects, the terms such as first, second, etc., have been used to distinguish one component from other components, rather than limiting.

In the following aspects, singular forms include plural forms unless apparently indicated otherwise contextually.

In the following aspects, the terms "include", "have", or the like, are intended to mean that there are features, or components, described herein, but do not preclude the possibility of adding one or more other features or components.

In the following aspects, when a portion, such as a film, a region, a component, etc., is present on or above another portion, this case may include not only a case where it is directly on the other portion, but also a case where another film, region, component, etc., is arranged between the portion and the other portion.

In the following aspects, terms such as connect or combine do not necessarily imply a direct and/or fixed connection or combination of two members, unless the context clearly indicates otherwise, and do not exclude the presence of another member between the two members.

In the drawings, the size of components may be exaggerated or reduced for convenience of description. For example, as the size and thickness of each component shown in the drawings are arbitrarily shown for convenience of description, the disclosure is not necessarily limited to the illustration.

Hereinafter, aspects of the disclosure will be described in detail with reference to the attached drawings, and in the description with reference to the drawings, identical or corresponding components are given the same reference numerals and redundant descriptions thereof will be omitted.

Hereinafter, 'cleaning the mask' may be defined as removing organic material on the mask by supplying a cleaning gas to the mask, and a 'cleaning process of the mask' may be defined as a process of removing organic material on the mask by supplying a cleaning gas to the mask.

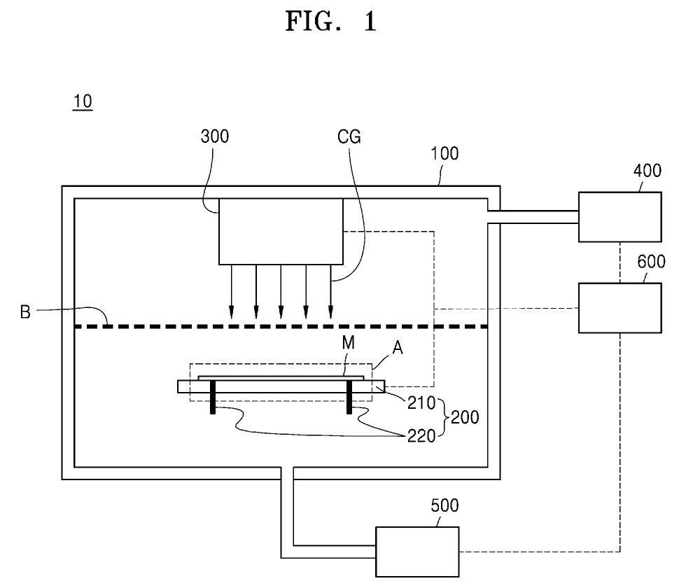

FIG. 1 schematically shows a mask cleaning device according to an aspect of the disclosure.

Referring to FIG. 1, a mask cleaning device 10 according to an aspect of the disclosure may include a chamber 100, a heating unit 200, a cleaning gas supply unit 300, a gas supply unit 400, a pump 500, and a control unit 600.

The chamber 100 may have an inner space separated from an outer space. The chamber 100 may have an inner space which is spatially and fluidly separated from the outer space to separate components placed therein from an external environment.

The chamber 100 may provide a cleaning space for a mask M. The chamber 100 may have a space in which the mask M is placed and through which a cleaning gas CG for cleaning the mask M may flow, thereby cleaning the mask M arranged in the space. The chamber 100 may provide a space in which the mask M may be cleaned by interaction with the cleaning gas CG without being affected by the external environment.

The mask M may be arranged on the heating unit 200. The heating unit 200 may support the mask M to adjust a position and a posture of the mask M in case that the mask M is cleaned inside the chamber 100, and may adjust a heating temperature value of a surface on which the mask M is arranged and transfer heat to the mask M.

In an aspect, the heating unit 200 may include a main body 210 and an elevating unit 220.

The main body 210 may contact and support the mask M. A surface of the main body 210 may come into contact with a surface of the mask M in a way to face the surface of the mask M, thereby supporting the mask M by contact. The mask M may be stably supported by coming into contact with the main body 210 of the heating unit 200 over a large area.

A temperature of the main body 210 may be adjusted. The heating unit 200 may include a heating source (not shown) or a cooling source (not shown) therein to adjust the temperature of the main body 210. The temperature of the main body 210 may be adjusted to transfer heat to or receive heat from other components with which the main body 210 comes into contact.

The main body 210 may heat the mask M. The main body 210 may be controlled such that the temperature thereof may be adjusted to heat the mask M supported by the main body 210 by contact. For example, the main body 210 may be controlled such that a temperature of a surface of the main body 210 facing the mask M is adjusted, thereby heating the mask M arranged on the main body 210.

The mask M may be placed on the main body 210 and may receive heat from the main body 210 to have a temperature value corresponding to the heating temperature. The organic material attached to the mask M may have a temperature increasing by the heat transferred from the main body 210, and may react with the cleaning gas CG during the cleaning process of the mask M described later.

The elevating unit 220 may support the mask M arranged on the main body 210. The elevating unit 220 may support the mask M by contacting the mask M on one side thereof. The elevating unit 220 may support the mask M in a direction in which the main body 210 and the mask M are arranged. Thus, the elevating unit 220 may support the mask M arranged on the main body 210 together with the main body 210.

A plurality of elevating units 220 may support the mask M. For example, the elevating units 220 may be arranged to face each other to stably support the mask M.

While it is shown in the drawing that two elevating units 220 have the shape of a shaft and are arranged side by side to support the mask M, the shape, number, and arrangement of the elevating units 220 are not limited thereto.

The elevating unit 220 may move relative to the main body 210. For example, the elevating unit 220 may move relative to the main body 210 in the direction in which the main body 210 and the mask M are arranged.

The elevating unit 220 may move the mask M relative to the main body 210. The elevating unit 220 may support the mask M in the direction in which the main body 210 and the mask M are arranged, and move relative to the main body 210, thereby allowing the mask M to move relative to the main body 210. The elevating unit 220 may arrange the mask M apart from the main body 210 or return the mask M arranged apart from the main body 210 back onto the main body 210.

The heating unit 200 may be arranged inside the chamber 100. Although not shown in the drawing, the heating unit 200 may be connected to an inside of the chamber 100 such that a relative position thereof with respect to the chamber 100 may be fixed. Thus, the heating unit 200 may provide a space in which the mask M may be stably arranged inside the chamber 100.

The cleaning gas supply unit 300 may generate the cleaning gas CG. The cleaning gas supply unit 300 may generate the cleaning gas CG by applying high energy to a source gas. For example, the cleaning gas supply unit 300 may supply, as the cleaning gas CG, plasma generated by supplying high electrical energy to the source gas through an electrode (not shown) or a coil (not shown) provided therein.

The cleaning gas supply unit 300 may supply the cleaning gas CG to the inside of the chamber 100. For example, the cleaning gas supply unit 300 may have an inner space fluidly connected to the outer side to diffuse the generated cleaning gas CG to outside the cleaning gas supply unit 300. The cleaning gas supply unit 300 may be arranged inside the chamber 100, and the inside and the outside of the cleaning gas supply unit 300 may be fluidly connected to diffuse the generated cleaning gas CG inside the chamber 100. Thus, the cleaning gas supply unit 300 may supply the cleaning gas CG to the mask M arranged inside the chamber 100.

The cleaning gas supply unit 300 may generate plasma. The cleaning gas supply unit 300 may generate plasma by using the source gas. For example, the cleaning gas supply unit 300 may generate plasma by applying energy to the source gas using the electrode (not shown) or coil (not shown) provided therein. The cleaning gas supply unit 300 may supply the generated plasma as the cleaning gas CG to the inside of the chamber 100.

The cleaning gas supply unit 300 may generate the cleaning gas CG containing radical species. The cleaning gas supply unit 300 may generate the cleaning gas CG including highly reactive radical species and supply the same to the mask M, thereby inducing a chemical reaction between the organic material on the mask M and the cleaning gas CG. The cleaning gas supply unit 300 may generate the cleaning gas CG including radical species to remove the organic material on the mask M.

In an aspect, the cleaning gas supply unit 300 may generate the cleaning gas CG including hydrogen radicals. The cleaning gas supply unit 300 may generate the cleaning gas CG including hydrogen radicals and supply the same to the mask M, thereby inducing a reaction between the organic material on the mask M and the hydrogen radicals.

The cleaning gas supply unit 300 may generate the cleaning gas CG including hydrogen radicals to effectively remove the organic material on the mask M. The hydrogen radicals may actively react with metal-doped organic material to more effectively remove the metal-doped organic material on the mask M. The cleaning gas supply unit 300 may supply the cleaning gas CG including hydrogen radicals to the mask M to effectively remove the metal-doped organic material on the mask M.

The cleaning gas supply unit 300 may generate the cleaning gas CG including hydrogen radicals to stably remove the organic material on the mask M. The hydrogen radicals may have relatively low energy and have high reactivity to specific chemical bonds, thus reacting with the organic material on the mask M while minimizing their impact on the mask M. Thus, the cleaning gas supply unit 300 may supply the cleaning gas CG including hydrogen radicals to the mask M, thereby maintaining structural stability of the mask M in cleaning.

The cleaning gas supply unit 300 may generate the cleaning gas CG including hydrogen radicals by using a gas including a combination of a hydrogen gas and water vapor as the source gas. For example, the cleaning gas supply unit 300 may supply energy to the hydrogen gas and the water vapor to generate plasma including hydrogen radicals. The cleaning gas supply unit 300 may also generate the cleaning gas CG by using the hydrogen gas or the water vapor as the source gas.

The gas supply unit 400 may be fluidly connected to the chamber 100. For example, the gas supply unit 400 may be fluidly connected to the chamber 100 by a flow path that fluidly connects the chamber 100 and the gas supply unit 400. The disclosure is not limited thereto, and the gas supply unit 400 may be arranged inside the chamber 100 such that the inner space and the outer space thereof are fluidly connected to each other. Thus, the gas supply unit 400 may supply an inert gas into the chamber 100.

The gas supply unit 400 may adjust a pressure inside the chamber 100. The gas supply unit 400 may adjust the amount of gas contained inside the chamber 100 by transferring the inert gas into the chamber 100. Thus, the gas supply unit 400 may adjust the pressure applied to the mask M arranged inside the chamber 100.

The gas supply unit 400 may adjust a density of the cleaning gas inside the chamber 100. The gas supply unit 400 may transfer the inert gas into the chamber 100 to adjust a ratio of the cleaning gas CG contained inside the chamber 100 to the inert gas. Thus, the gas supply unit 400 may adjust a frequency at which the organic material on the mask M arranged inside the chamber 100 interacts with the cleaning gas CG.

The gas supply unit 400 may adjust a distribution of the cleaning gas CG inside the chamber 100. In an aspect, the gas supply unit 400 may supply an argon (Ar) gas into the chamber 100. The argon gas has a high atomic weight such that the mixed cleaning gas CG may be distributed in a lower portion of the chamber 100.

The gas supply unit 400 may adjust a temperature of the inert gas transferred into the chamber 100. The temperature-adjusted inert gas may be transferred into the chamber 100 by the gas supply unit 400, and thus may receive heat from or transfer heat to the chamber 100 and components arranged inside the chamber 100. The gas supply unit 400 may adjust the temperatures of the chamber 100 and each component therein by adjusting the temperature of the inert gas transferred into the chamber 100.

The pump 500 may discharge the fluid inside the chamber 100 to the outside. The pump 500 may be fluidly connected to the inside of the chamber 100 to transfer the fluid inside the chamber 100 to the outside. The pump 500 may form a flow of the fluid using power, and may be, but not limited to, a rotary vane pump or a turbo pump, but is not limited thereto.

The pump 500 may adjust the pressure inside the chamber 100. The pump 500 may determine the amount of fluid contained inside the chamber 100 having a constant volume by transferring the fluid inside the chamber 100 to the outside. Thus, the pump 500 may adjust the pressure applied to the mask M arranged inside the chamber 100.

The pump 500 may maintain the pressure inside the chamber 100 constant. The pump 500 may maintain the pressure inside the chamber 100 constant by withdrawing, from the chamber 100, fluid of an amount corresponding to the amount of cleaning gas CG supplied from the cleaning gas supply unit 300 and the amount of inert gas supplied from the gas supply unit 400. Thus, cleaning of the mask M may be stably performed inside the chamber 100.

The pump 500 may maintain the pressure inside the chamber 100 at a low pressure. The pump 500 may minimize the amount of cleaning gas CG remaining around the mask M by maintaining the amount of fluid stored inside the chamber 100 small. In case that the amount of cleaning gas CG remaining around the mask M is minimized, the cleaning gas CG reacting with the organic material on the mask M may be quickly discharged to outside the chamber 100. Thus, the amount of foreign substances remaining on the mask M in cleaning of the mask M may be minimized.

The control unit 600 may control the heating unit 200, the cleaning gas supply unit 300, the gas supply unit 400, and the pump 500. The control unit 600 may be electrically connected to the heating unit 200, the cleaning gas supply unit 300, the gas supply unit 400, and the pump 500, and may transmit a control signal to each component to control driving of each component.

The control unit 600 may adjust a temperature of the heating unit 200. The control unit 600 may control the heating unit 200 to adjust the heating temperature value of the main body 210 on which the mask M is arranged. The control unit 600 may transfer heat to the mask M arranged on the main body 210 by adjusting the heating temperature. The control unit 600 may adjust the temperature of the main body 210 to transfer heat to the organic material on the mask M.

In an aspect, the control unit 600 may control the heating unit 200 such that the heating temperature value of the main body 210 is equal to or greater than a first process temperature value. The control unit 600 may control the heating unit 200 such that the mask M arranged on the main body 210 has a temperature value corresponding to the first process temperature value. The control unit 600 may promote the reaction between the organic material and the cleaning gas CG by causing the organic material on the mask M to have a temperature value corresponding to the first process temperature value.

The control unit 600 may control the heating unit 200 during the cleaning time to adjust the heating temperature value of the main body 210. The control unit 600 may control the heating unit 200 such that the heating temperature value of the main body 210 is equal to or greater than the first process temperature value during the cleaning time in case that the cleaning gas supply unit 300 supplies the cleaning gas CG to the mask M during the cleaning time. The organic material on the mask M may have a temperature value corresponding to the first process temperature value while the cleaning gas CG is being supplied. Thus, cleaning of the mask M may be efficiently performed.

Hereinafter, 'activation' may be defined as changing a state of organic material such that that a chemical reaction between the organic material and the radical species may be promoted.

In an aspect, the control unit 600 may control the heating unit 200 such that the heating temperature value of the main body 210 is equal to or greater than a second process temperature value. The control unit 600 may control the heating unit 200 such that the mask M arranged on the main body 210 has a temperature value corresponding to the second process temperature value. The control unit 600 may activate the organic material on the mask M by causing the organic material on the mask M to have a temperature value corresponding to the second process temperature value.

For example, the control unit 600 may control the heating unit 200 such that the heating temperature value is equal to or greater than the second process temperature value before the cleaning gas supply unit 300 supplies the cleaning gas CG to the mask M. The control unit 600 may control the heating unit 200 before the cleaning gas CG is supplied to the mask M, thus pre-treating the organic material on the mask M.

The control unit 600 may control the heating unit 200 during the pre-treatment time before the cleaning gas supply unit 300 supplies the cleaning gas CG to the mask M. The control unit 600 may control the heating unit 200 such that the organic material on the mask M has a temperature value corresponding to the second process temperature value during the pre-treatment time before the cleaning gas CG is supplied to the mask M. The control unit 600 may pre-treat the organic material on the mask M before cleaning during the pre-treatment time. Thus, cleaning of the mask M may be actively performed.

The control unit 600 may control the elevating unit 220 such that the mask M and the main body 210 are spaced apart from each other. The control unit 600 may control the elevating unit 220 supporting the mask M to arrange the mask M apart from the main body 210. The control unit 600 may separate the mask M and the main body 210 to form a space in which the cleaning gas CG may flow between the mask M and the main body 210. The control unit 600 may separate the mask M from the main body 210 such that a bottom surface of the mask M is exposed to the cleaning gas CG.

Hereinafter, the 'bottom surface' may be defined as meaning a surface of the mask M facing the main body 210, and a 'top surface' may be defined as meaning the other surface opposite to the surface of the mask M.

Hereinafter, a 'first time' may be defined as a time from when the cleaning gas CG is supplied to the mask M until top organic material TOM is removed, and a 'second time' may be defined as a time from when the cleaning gas CG enters between the mask M spaced apart from the main body 210 and the main body 210 until bottom organic material BOM is removed.

The control unit 600 may control the elevating unit 220 such that the mask M is spaced apart from the main body 210 after the first time has elapsed. The control unit 600 may control the elevating unit 220 such that the mask M and the main body 210 are spaced apart from each other after the cleaning gas CG starts to be supplied from the cleaning gas supply unit 300. The control unit 600 may arrange the mask M apart from the main body 210 after the cleaning gas CG is supplied to the mask M for the first time to remove the top organic material TOM. The control unit 600 may cause the bottom organic material BOM to be exposed to the cleaning gas CG after the top organic material TOM of the mask M is removed. Thus, the control unit 600 may improve the cleaning efficiency of the mask M during cleaning and prevent re-contamination of the mask M.

The control unit 600 may control the elevating unit 220 such that the mask M returns to the main body 210 after the second time has elapsed. The control unit 600 may return the mask M to the main body 210 after the cleaning gas CG enters between the mask M and the main body 210 and reacts with the bottom organic material BOM for a certain time. The control unit 600 may return the mask M to the main body 210 after the bottom organic material BOM is removed by the cleaning gas CG. Thus, a removal rate of organic material on the mask M may be improved, and after cleaning of the mask M is completed, the mask M may be stably arranged inside the chamber 100.

The control unit 600 may return the mask M to the main body 210 after the cleaning time has elapsed from the time when the cleaning gas CG starts to be supplied from the cleaning gas supply unit 300. The control unit 600 may move the mask M such that the mask M is supported by the main body 210 after the organic material on the top and bottom surfaces of the mask M is removed by the cleaning gas CG. Thus, after cleaning of the mask M is completed, the mask M may be stably arranged inside the chamber 100.

The control unit 600 may control the cleaning gas supply unit 300. The control unit 600 may control the cleaning gas supply unit 300 to adjust production and discharge amounts of the cleaning gas CG. The control unit 600 may control the cleaning gas supply unit 300 to adjust the amount of cleaning gas CG supplied into the chamber 100. The control unit 600 may control the cleaning gas supply unit 300 to adjust the amount of cleaning gas CG supplied to the mask M.

For example, the control unit 600 may control the cleaning gas supply unit 300 to adjust a timing to supply the cleaning gas CG to the mask M. The control unit 600 may determine a timing for the cleaning gas supply unit 300 to generate and discharge the cleaning gas CG, such that the cleaning gas CG may be supplied after the pre-treatment of the organic material attached to the mask M is completed. Thus, the cleaning efficiency of the mask M may be improved.

The control unit 600 may control the cleaning gas supply unit 300 to adjust the temperature of the cleaning gas CG. The control unit 600 may adjust the temperature of the cleaning gas CG supplied to the mask M from the cleaning gas supply unit 300 to determine a temperature difference between the cleaning gas CG and the mask M.

For example, the control unit 600 may control the cleaning gas supply unit 300 to supply the cleaning gas CG having a temperature value corresponding to the heating temperature value of the main body 210 to the mask M. The control unit 600 may be in contact with the main body 210 to supply the cleaning gas CG having the temperature value corresponding to the heating temperature value to the mask M having a temperature value corresponding to the heating temperature. Thus, the temperature of the organic material attached to the mask M may be maintained constant, thereby maintaining the cleaning efficiency of the mask M.

The control unit 600 may adjust the amount of inert gas discharged from the gas supply unit 400. The control unit 600 may adjust the amount of inert gas supplied from the gas supply unit 400 to the chamber 100 to determine the amount of inert gas contained inside the chamber 100. The control unit 600 may determine the pressure inside the chamber 100 by adjusting the amount of inert gas discharged into the chamber 100 having an inner space of a preset volume.

The control unit 600 may adjust the temperature of the inert gas discharged from the gas supply unit 400. The control unit 600 may adjust the temperature of the inert gas supplied from the gas supply unit 400 to the chamber 100 to transfer heat with the chamber 100 and a component arranged therein.

The control unit 600 may adjust the temperature of the inert gas supplied to the chamber 100 during pre-treatment of the mask M.

In an aspect, the control unit 600 may control the gas supply unit 400 to supply the inert gas having the temperature value corresponding to the heating temperature value of the main body 210 into the chamber 100.

In case that the main body 210 has the second process temperature value, the control unit 600 may control the gas supply unit 400 to supply the inert gas having a temperature value corresponding to the second process temperature value into the chamber 100. That is, in case that the heating unit 200 pre-treats the organic material on the mask M by adjusting the temperature of the main body 210, the control unit 600 may supply the inert gas having the second process temperature value to promote the pre-treatment of the mask M.

In an aspect, the control unit 600 may control the gas supply unit 400 to supply the inert gas having the temperature value corresponding to the second process temperature value into the chamber 100. The control unit 600 may pre-treat organic material on the mask M by supplying the inert gas having the temperature value corresponding to the second process temperature value into the chamber 100.

The control unit 600 may control the pump 500 to discharge the fluid inside the chamber 100 to the outside. The control unit 600 may operate the pump 500 to discharge the fluid inside the chamber 100 to the outside, or stop the operation of the pump 500 to fluidly separate the inside and outside of the chamber 100. Thus, the control unit 600 may control the pump 500 to determine the amount of fluid contained in the chamber 100.

The control unit 600 may control the pump 500 to adjust the pressure inside the chamber 100. For example, the control unit 600 may control the pump 500 such that a gas of an amount corresponding to the amount of gas supplied into the chamber 100 from the cleaning gas supply unit 300 and the gas supply unit 400 is discharged to outside the chamber 100. The pump 500 may maintain the pressure inside the chamber 100 constant.

In an aspect, the control unit 600 may control the pump 500 to maintain the pressure inside the chamber 100 close to vacuum. The control unit 600 may activate air flow inside the chamber 100 by keeping the amount of gas stored inside the chamber 100 close to 0. The control unit 600 may quickly discharge the cleaning gas CG having finished reacting with the organic material on the mask M to outside the chamber 100 by activating the air flow inside the chamber 100. Thus, the control unit 600 may increase the cleaning efficiency of the mask M.

The mask cleaning device 10 may further include a baffle B. The baffle B may interact with the cleaning gas CG supplied from the cleaning gas supply unit 300 to make the flow of the cleaning gas CG supplied into the chamber 100 uniform.

The baffle B may be arranged between the cleaning gas supply unit 300 and the mask M. The baffle B may be arranged between the cleaning gas supply unit 300 and the mask M to control the flow of the cleaning gas CG discharged from the cleaning gas supply unit 300 such that the cleaning gas CG is supplied evenly to each part of the mask M.

The baffle B may have a plurality of holes. The baffle B may include a plurality of holes communicating with a surface facing the cleaning gas supply unit 300 and the other surface opposite thereto. The baffle B may ensure that the cleaning gas CG supplied from the cleaning gas supply unit 300 has a uniformly formed flow while passing through the plurality of holes.

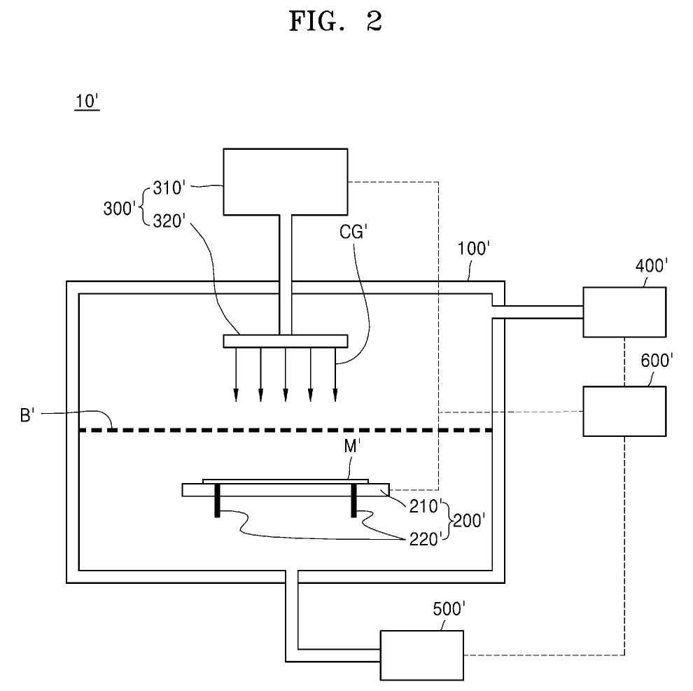

FIG. 2 shows a mask cleaning device according to another aspect of the disclosure.

Referring to FIG. 2, a mask cleaning device 10' according to another aspect of the disclosure is different from the mask cleaning device 10 according to an aspect of the disclosure only in a specific shape of the cleaning gas supply unit 300, and therefore, the following description will focus on differences.

A cleaning gas supply unit 300' according to another aspect of the disclosure may include a cleaning gas generation unit 310' and a spray unit 320'.

The cleaning gas generation unit 310' may generate plasma. The cleaning gas generation unit 310' may generate plasma using the source gas transferred from the outside. For example, the cleaning gas generation unit 310' may generate plasma by applying energy to the source gas using an electrode or a coil provided therein.

The cleaning gas generation unit 310' may generate plasma including radical species. The cleaning gas generation unit 310' may generate plasma including hydrogen radicals. The cleaning gas generation unit 310' may generate plasma including hydrogen radicals by using a hydrogen gas, water vapor, or a gas combining the hydrogen gas with the water vapor.

The cleaning gas generation unit 310' may have an inner space separated from the cleaning space of a chamber 100'. The cleaning gas generation unit 310' may have an inner space which is spatially and fluidly separated from the cleaning space of the chamber 100', such that the mask M may be separated from events occurring during a process of generating plasma in the cleaning gas generation unit 310'. For example, the cleaning gas generation unit 310' may have an inner space independent of the cleaning space of the chamber 100', such that the mask M may be separated from an arc generated during generation of the plasma. Thus, the structural stability of the mask M during the cleaning process may be improved.

The cleaning gas generation unit 310' may be connected to the spray unit 320'. The cleaning gas generation unit 310' may be fluidly connected to the spray unit 320' such that the generated plasma may be transferred to the spray unit 320'. The plasma generated in the cleaning gas generation unit 310' may be transferred to the spray unit 320' and supplied into the chamber 100'.

The cleaning gas generation unit 310' may transfer a part of the generated plasma to the spray unit 320'. For example, the cleaning gas generation unit 310' may selectively transfer radical species of the generated plasma to the spray unit 320'. The cleaning gas generation unit 310' may selectively transfer hydrogen radicals of the generated plasma to the spray unit 320'.

The cleaning gas generation unit 310' may selectively transfer the hydrogen radicals of the generated plasma to the spray unit 320', thereby enabling interaction between the hydrogen radicals and the organic material on the mask M'. The cleaning gas generation unit 310' may transfer the hydrogen radicals to the spray unit 320' such that the hydrogen radicals may be sprayed as a cleaning gas CG' from the spray unit 320'. Thus, the mask M' may be cleaned stably.

The spray unit 320' may spray the cleaning gas CG' transferred from the cleaning gas generation unit 310' into the chamber 100'. The spray unit 320' may supply the cleaning gas CG' to the mask M arranged inside the chamber 100' by spraying the cleaning gas CG' into the chamber 100'. Thus, the organic material on the mask M may interact with the cleaning gas CG', and cleaning of the mask M' may be achieved.

The spray unit 320' may be arranged to face a surface of a heating unit 200' where the mask M' is arranged. The spray unit 320' may be arranged to face a surface of a main body 210' on which the mask M' is arranged. The spray unit 320' may be oriented toward the mask M' arranged on a surface of the main body 210.

The spray unit 320' may spray the cleaning gas CG' toward the mask M. The cleaning gas CG' may be sprayed toward the mask M' to actively react with the organic material on the mask M'. Thus, the cleaning efficiency of the mask M' may increase.

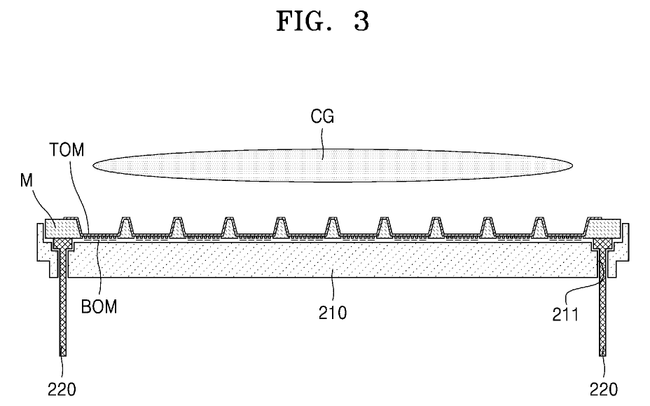

FIG. 3 is a view enlarging a portion A of FIG. 1.

Referring to FIG. 3, the heating unit 200 may include the main body 210 in which the mask M is arranged, and the elevating unit 220 which elevates and lowers the mask M.

In an aspect, the elevating unit 220 may be connected to the main body 210. The elevating unit 220 may be arranged inside an elevating hole 211 formed in the main body 210. The elevating unit 220 may be arranged inside the elevating hole 211 and may move relative to the main body 210 in a direction in which the elevating hole 211 extends. Thus, the mask M supported by the elevating unit 220 may move relative to the main body 210.

In the drawing, the elevating unit 220 may be shown as being arranged inside the elevating hole 211 formed in the main body 210 and being connected to the main body 210, but the arrangement and shape of the elevating unit 220 are not limited thereto. For example, the elevating unit 220 may be provided as an independent component without being connected to the main body 210 and may move relative to the main body 210 such that the supported mask M may be spaced apart from the main body 210.

The mask M may be cleaned by receiving the cleaning gas CG while being arranged on the heating unit 200.

The mask M may be arranged on the heating unit 200. The mask M may be arranged on the main body 210. The mask M may be supported by the main body 210 by contact. A surface of the mask M may be supported by a surface of the main body 210 by contact, thus being cleaned while being stably arranged inside the chamber 100.

In an aspect, the mask M may be supported by the main body 210 by contact and at the same time, may be supported by the elevating unit 220 by contact. The mask M may be supported by the main body 210 and the elevating unit 220 of the heating unit 200, such that in case that the elevating unit 220 moves relative to the main body 210, the elevating unit 220 may be separated from the main body 210.

The elevating unit 220 may determine the position of the mask M. The elevating unit 220 may be lowered to bring the mask M and the main body 210 into contact with each other, and may be elevated to separate the mask M from the main body 210.

Hereinafter, a 'top organic material' may be defined to mean organic material attached to the top surface of the mask M, and a 'bottom organic material' may be defined to mean organic material attached to the bottom surface of the mask M.

The top surface of the mask M may be exposed to the cleaning gas CG. The top surface of the mask M may be exposed to the cleaning gas CG, such that the top organic material TOM attached to the top surface of the mask M may be exposed to the cleaning gas CG. The top organic material TOM may be separated from the mask M by reacting with the cleaning gas CG. Thus, cleaning of the top surface of the mask M may be achieved.

The elevating unit 220 may clean the top surface of the mask M by bringing the mask M and the main body 210 into contact during the cleaning time of the top surface. The elevating unit 220 may allow the top organic material TOM on the mask M to be separated from the mask M by allowing the cleaning time of the top surface to have elapsed while the top organic material TOM is exposed to the cleaning gas CG. The elevating unit 220 may concentrate the cleaning gas CG on the top surface of the mask M by bringing the mask M into contact with the main body 210 during the cleaning time of the top surface. Thus, the cleaning efficiency of the top organic material TOM arranged on the mask M may increase.

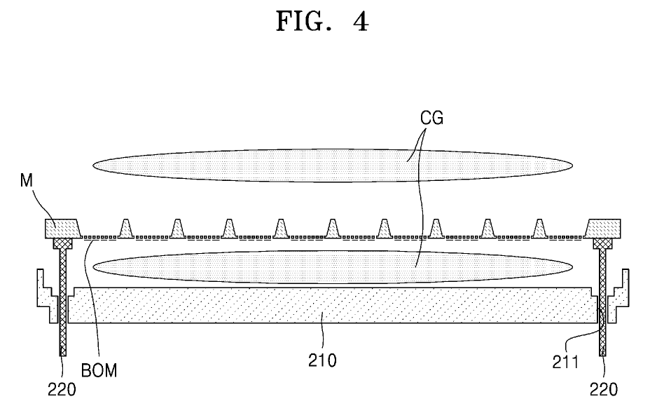

FIG. 4 is a view showing some components of FIG. 3 in operation.

Referring to FIG. 4, the elevating unit 220 may operate to elevate the mask M.

The elevating unit 220 may operate to move up, thereby allowing the mask M supported by contact to be spaced apart from the main body 210. The elevating unit 220 may provide a space in which the cleaning gas CG may be arranged between the mask M and the main body 210 by arranging the mask M apart from the main body 210.

The elevating unit 220 may expose the bottom surface of the mask M to the cleaning gas CG. The elevating unit 220 may arrange the mask M apart from the main body 210 such that the bottom organic material BOM on the mask M is exposed to the cleaning gas CG. The elevating unit 220 may move the mask M such that the bottom surface of the mask M may be cleaned.

The elevating unit 220 may elevate the mask M after the cleaning time of the top surface has elapsed from when the cleaning gas CG is supplied to the mask M. The elevating unit 220 may elevate the mask M after cleaning is completed during the cleaning time of the top surface while the mask M is in contact with the main body 210.

The elevating unit 220 may concentrate the cleaning gas CG on the top organic material TOM by cleaning the top surface during the cleaning time of the top surface, and may elevate the mask M to concentrate the cleaning gas CG on the bottom organic material BOM. Thus, the cleaning efficiency of the bottom organic material BOM arranged on the mask M may be improved.

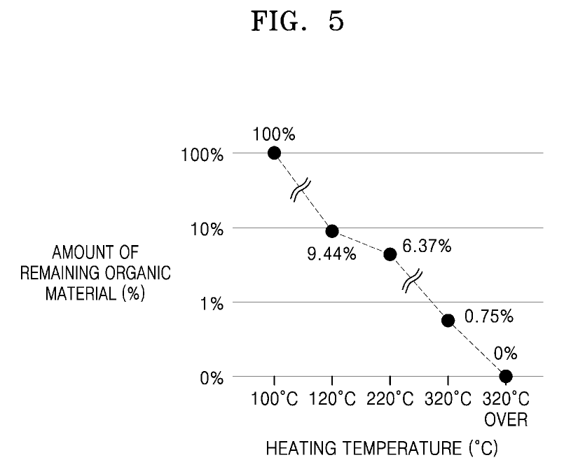

FIG. 5 is an experimental result graph showing the amount of organic material remaining on a mask after cleaning with respect to a heating temperature.

Referring to FIG. 5, it may be seen that as the heating temperature value increases during cleaning of the mask M, the amount of organic material remaining on the mask M after cleaning decreases. As the first process temperature value increases, the cleaning efficiency of the mask M may increase.

In an aspect, the first process temperature value may be at least 110 °C. In case that the first process temperature value is at least 110 ℃, the amount of organic material remaining on the mask M after cleaning is approximately 9.44 %. In case that the first process temperature value is at least 110 ℃, the amount of residual organic material may decrease rapidly compared to a case where the first process temperature value is 100 ℃. In case that the first process temperature value is at least 110 ℃, the cleaning efficiency of the mask M may increase rapidly.

The first process temperature value may be at least 300 °C. Referring to FIG. 5, in case that the first process temperature value is at least 110 ℃ but not more than 220 ℃, the amount of organic material remaining on the mask M after cleaning is 9.44 % to 6.37 %. In case that the first process temperature value is at least 300 ℃, the amount of residual organic material may decrease rapidly compared to a case where the first process temperature value is not more than 220 ℃. In case that the first process temperature value is at least 300 ℃, the cleaning efficiency of the mask M may increase rapidly.

The first process temperature value may be at least 320 °C. Referring to FIG. 5, in case that the first process temperature value is at least 320 °C, the amount of organic material remaining on the mask M after cleaning is 0 %. In case that the amount of organic material remaining on the mask M is 0 % after cleaning, in spite of reuse of the mask M after cleaning a plurality of times, the amount of organic material remaining on the mask M due to accumulation may be close to 0 %. In case that the first process temperature value is at least 320 ℃, an initial state of the mask M may be maintained in spite of reuse of the mask M a plurality of times. In case that the first process temperature value is at least 320 ℃, the reuse efficiency of the mask M may increase rapidly.

In an aspect, the first process temperature value may be greater than the second process temperature value. The heating temperature value of the heating unit 200 during the cleaning process in which the cleaning gas CG is supplied to the mask M may be greater than the heating temperature value of the heating unit 200 during the pre-treatment process of the mask M before the cleaning process.

As the second process temperature value is lower than the first process temperature value, the hardness of the organic material on the mask M may not be high. In case that the heating temperature value is high during the pre-treatment process, the organic material on the mask M may be hardened depending on the pre-treatment. Therefore, by setting the second process temperature value lower than the first process temperature value, the hardness of the organic material attached to the mask M after pre-treatment may be maintained low. By setting the second process temperature value lower than the first process temperature value, the organic material may be caused to smoothly react with the cleaning gas CG during cleaning of the mask M. Thus, the cleaning efficiency of the mask M may be improved.

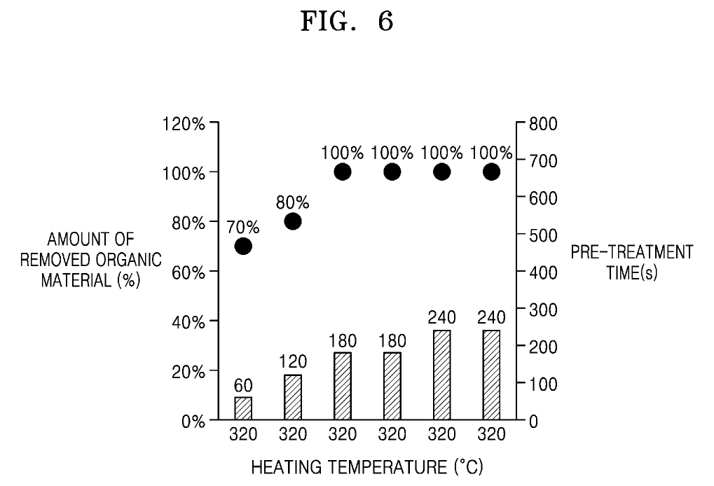

FIG. 6 is an experimental result graph showing the amount of organic material remaining on a mask after cleaning with respect to a pre-treatment time.

Referring to FIG. 6, it may be seen that as the pre-treatment temperature increases during cleaning of the mask M, the amount of organic material removed from the mask M after cleaning increases. As the pre-treatment temperature increases during cleaning of the mask M, the amount of organic material remaining on the mask M after cleaning decreases.

The pre-treatment time may be at least 180 seconds. In case that the pre-treatment time is at least 180 seconds, the amount of organic material remaining on the mask M after cleaning is 0 %. In case that the amount of organic material remaining on the mask M is 0 % after cleaning of the mask M, in spite of reuse of the mask M after cleaning a plurality of times, the amount of organic material remaining on the mask M due to accumulation may be close to 0 %. In case that the pre-treatment time is at least 180 seconds, the initial state of the mask M may be maintained in spite of reuse of the mask M a plurality of times. Thus, in case that the pre-treatment time is at least 180 seconds, the reuse efficiency of the mask M may increase rapidly.

In an aspect, the pre-treatment time may be less than the cleaning time. In case that the pre-treatment time is less than the cleaning time, the hardness of the organic material attached to the mask M may be maintained low. In case that the pre-treatment time is less than the cleaning time, the process time for cleaning the mask M may be shortened.

In case that the pressure inside the chamber 100 increases during cleaning of the mask M, the frequency at which the organic material on the mask M interacts with the cleaning gas CG may increase. In case that the pressure inside the chamber 100 increases during cleaning of the mask M, the frequency at which the organic material on the mask M reacts with the radical species such as the hydrogen radicals may increase. Thus, as the pressure inside the chamber 100 increases during cleaning of the mask M, the cleaning efficiency of the mask M may increase.

In an aspect, the pressure inside the chamber 100 during cleaning of the mask M may be at least 1500 mT. In case that the pressure inside the chamber 100 is at least 1500 mT during cleaning of the mask M, the amount of organic material remaining on the mask M may be close to 0% after cleaning is completed. In case that the amount of organic material remaining on the mask M is 0 % after cleaning of the mask M, in spite of reuse of the mask M after cleaning a plurality of times, the amount of organic material remaining on the mask M due to accumulation may be close to 0 %. In case that the pressure inside the chamber 100 during cleaning of the mask M is at least 1500 mT, the initial state of the mask M may be maintained in spite of reuse of the mask M a plurality of times. Thus, in case that the pre-treatment time is at least 180 seconds, the reuse efficiency of the mask M may increase rapidly.

In another aspect, the pressure inside the chamber 100 during cleaning of the mask M may be at least 5 Torr (T). In case that the pressure inside the chamber 100 exceeds 5T during cleaning of the mask M, the amount of cleaning gas CG remaining inside the chamber 100 during the cleaning process may increase. As the cleaning gas reacting with the organic material on the mask M during the cleaning process remains inside the chamber 100, the mask M may be contaminated again. Thus, by maintaining the pressure inside the chamber 100 as being not more than 10 T during cleaning of the mask M, the cleaning efficiency of the mask M may be improved.

The mask cleaning device according to aspects of the disclosure may maximize the cleaning efficiency of the mask by adjusting the temperature of the mask. The mask cleaning device according to aspects of the disclosure may improve the cleaning efficiency of the mask by adjusting the temperature of the heating unit where the mask is arranged during the mask cleaning process, and may maximize the cleaning efficiency of the mask by pre-treating organic material on the mask before the mask cleaning process. The mask cleaning device according to aspects of the disclosure may maximize cleaning efficiency by generating cleaning gas in a space separate from the cleaning space of the mask and controlling the pressure within the cleaning space.

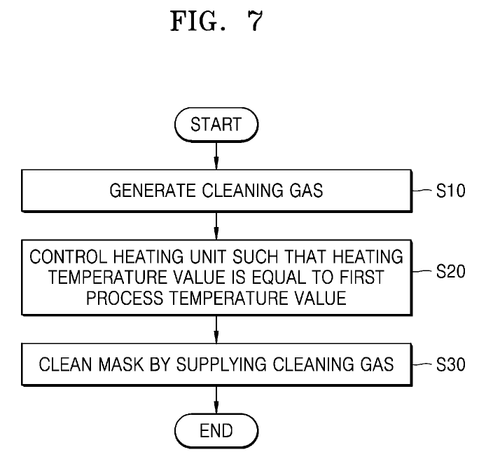

FIG. 7 is a flowchart showing a mask cleaning method according to an aspect of the disclosure.

Referring to FIG. 7, a mask cleaning method according to an aspect of the disclosure may include operation S10 of generating a cleaning gas, operation S20 of controlling a heating unit such that a heating temperature value is equal to a first process temperature value, and operation S30 of cleaning a mask.

In operation S10 of generating the cleaning gas, the cleaning gas CG may be generated from the source gas. In operation S10 of generating the cleaning gas, the cleaning gas CG containing radical species may be generated from the source gas using the cleaning gas supply unit 300. For example, operation S10 of generating the cleaning gas, the cleaning gas CG including hydrogen radicals may be generated.

In operation S10 of generating the cleaning gas, plasma may be generated using the source gas. In operation S10 of generating the cleaning gas, plasma may be generated by supplying high energy to the source gas. For example, in operation S10 of generating the cleaning gas, the plasma may be generated by supplying high electrical energy to the source gas using an electrode or a coil.

In operation S10 of generating the cleaning gas, the plasma may be supplied as the cleaning gas CG, or radical species or hydrogen radicals may be supplied as the cleaning gas CG. For example, in operation S10 of generating the cleaning gas, the plasma may be generated using the cleaning gas generation unit 310' and used as the cleaning gas CG, or radical species or hydrogen radicals of the generated plasma may be used as the cleaning gas CG.

In operation S20 of controlling the heating unit such that the heating temperature value is equal to the first process temperature value, the heating unit 200 may be controlled such that the heating temperature value of the main body 210 is greater than or equal to the first process temperature value. In operation S20 of controlling the heating unit such that the heating temperature value is equal to the first process temperature value, the heating temperature value may be adjusted such that the mask M arranged on the main body 210 has a temperature value corresponding to the first process temperature value. In operation S20 of controlling the heating unit such that the heating temperature value is equal to the first process temperature value, the heating unit 200 may be controlled to promote reaction between the organic material on the mask M and the cleaning gas CG.

In an aspect, in operation S20 of controlling the heating unit such that the heating temperature value is equal to the first process temperature value, the heating unit 200 may be controlled during the cleaning time to adjust the heating temperature. In operation S20 of controlling the heating unit such that the heating temperature value is equal to the first process temperature value, in case that the cleaning gas supply unit 300 supplies the cleaning gas CG to the mask M during the cleaning time, the heating unit 200 may be controlled such that the heating temperature value of the main body 210 during the cleaning time is equal to the first process temperature value. The organic material on the mask M may have a temperature value corresponding to the first process temperature value while the cleaning gas CG is being supplied. Thus, the cleaning process of the mask M may be efficiently performed.

In operation S30 of cleaning the mask, the cleaning gas CG may be supplied to the mask M to remove the organic material on the mask M. In operation S30 of cleaning the mask, the organic material on the mask M may be separated from the mask M by inducing reaction between the organic material on the mask M and the cleaning gas CG.

In operation S30 of cleaning the mask, the reaction between the organic material on the mask M and the cleaning gas CG may be promoted by spraying the cleaning gas CG toward the mask M. For example, in operation S30 of cleaning the mask, the cleaning efficiency of the mask M may be improved by spraying the cleaning gas CG to the mask M using the spray unit 320' arranged to face a surface of the main body 210.

In operation S30 of cleaning the mask, the cleaning gas CG may be supplied to the mask M while the heating temperature value of the heating unit 200 is the first process temperature value. In operation S30 of cleaning the mask, the cleaning gas CG may be supplied to the mask M arranged on the main body 210 of the heating unit 200 while the mask M has a temperature value corresponding to the first process temperature value. Thus, the removal rate of the organic material in cleaning of the mask M may be improved.

In operation S30 of cleaning the mask, the cleaning gas CG may be supplied to the mask M during the cleaning time. In operation S30 of cleaning the mask, the organic material on the mask M may be exposed to the cleaning gas CG during the cleaning time. In operation S30 of cleaning the mask, the organic material may be separated from the mask M by reacting with the cleaning gas CG during the cleaning time. In operation S30 of cleaning the mask, a sufficient time may be provided for the organic material on the mask M to react with the cleaning gas CG, thereby improving the removal rate of the organic material during cleaning of the mask M.

In an aspect, operation S20 of controlling the heating unit such that the heating temperature value is equal to the first process temperature value and operation S30 of cleaning the mask may be performed simultaneously. While controlling the heating unit 200 during the cleaning time in operation S20 of controlling the heating unit to have the first process temperature value, in operation S30 of cleaning the mask, the cleaning gas CG may be supplied to the mask M during the cleaning time using the cleaning gas supply unit 300. The organic material attached to the mask M may react with the cleaning gas CG at a temperature value corresponding to the first process temperature value during the cleaning time. Thus, the cleaning efficiency of the mask M may be improved.

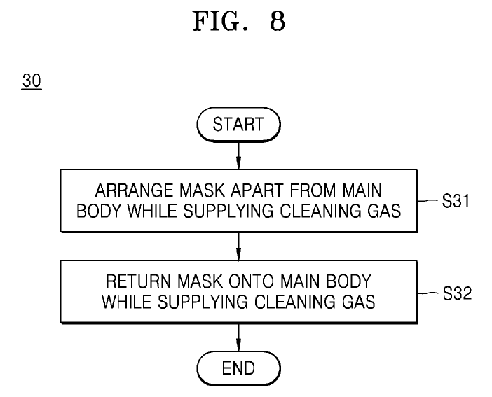

FIG. 8 is a flowchart showing in detail some operations of FIG. 7.

Referring to FIG. 8, operation S30 of cleaning the mask may include operation S31 of arranging the mask apart from the main body and operation S32 of returning the mask onto the main body.

In operation S31 of arranging the mask apart from the main body, the mask M may be arranged apart from the main body 210 using the elevating unit 220. In operation S31 of arranging the mask apart from the main body, the mask M may be elevated using the elevating unit 220.

In operation S31 of arranging the mask apart from the main body, a gap may be formed between the mask M and the main body 210 during the supply of the cleaning gas CG. In operation S31 of arranging the mask apart from the main body, a space which the cleaning gas CG may enter may be formed between the mask M and the main body 210. In operation S31 of arranging the mask apart from the main body, the bottom surface of the mask M may be exposed to the cleaning gas CG. Thus, the bottom organic material BOM attached to the mask M may be removed by reacting with the cleaning gas CG.

In operation S31 of arranging the mask apart from the main body, the mask M may be arranged apart from the main body 210 after an elapse of the first time. In operation S31 of arranging the mask apart from the main body, the mask M may be arranged apart from the main body 210 after the cleaning gas CG starts to be supplied. In operation S31 of arranging the mask apart from the main body, after the cleaning gas CG may be supplied to the mask M to remove the top organic material TOM, the mask M may be arranged apart from the main body 210. Thus, in operation S31 of arranging the mask apart from the main body, the bottom organic material BOM may be exposed to the cleaning gas CG after the top organic material TOM of the mask M is removed. Thus, in operation S31 of arranging the mask apart from the main body, the position of the mask M may be adjusted to improve the cleaning efficiency of the mask M during cleaning and prevent re-contamination of the mask M.

In operation S31 of arranging the mask apart from the main body, the temperature of the cleaning gas CG supplied to the mask M may be adjusted. In operation S31 of arranging the mask apart from the main body, the cleaning gas supply unit 300 may be controlled such that the cleaning gas CG has a temperature value corresponding to the first process temperature value. Thus, in operation S31 of arranging the mask apart from the main body, even in case that the mask M is arranged apart from the main body 210, the mask M may have a temperature value corresponding to the first process temperature value, such that the reaction between the organic material and the cleaning gas CG may occur actively.

In operation S32 of returning the mask onto the main body, the mask M may be returned to the main body 210 using the elevating unit 220. In operation S32 of returning the mask onto the main body, the mask M may be lowered using the elevating unit 220.

In operation S32 of returning the mask onto the main body, the elevating unit 220 may be controlled such that the mask M returns to the main body 210 after an elapse of the second time. In operation S32 of returning the mask onto the main body, the cleaning gas CG may enter between the mask M and the main body 210 to react with the bottom organic material BOM for a certain time and return the mask M to the main body 210. In operation S32 of returning the mask onto the main body, after the bottom organic material BOM is removed from the cleaning gas CG, the mask M may be returned onto the main body 210. Thus, a removal rate of organic material on the mask M may be improved, and after cleaning of the mask M is completed, the mask M may be stably arranged inside the chamber 100.

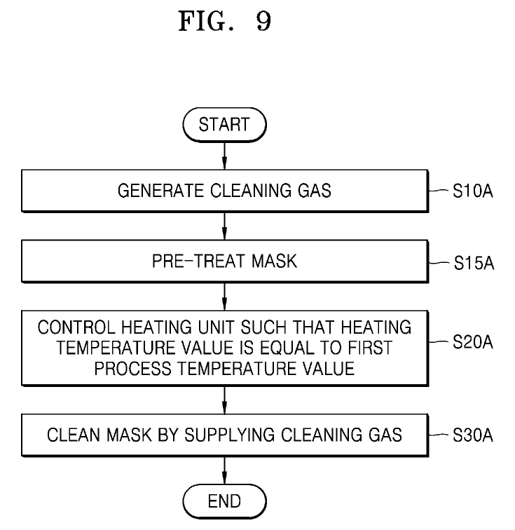

FIG. 9 is a flowchart showing a mask cleaning method according to another aspect of the disclosure.

The mask cleaning method according to another aspect of the disclosure may be different from the mask cleaning method according to an aspect of the disclosure in that some operations are added, and thus differences will be mainly described.

Referring to FIG. 9, a mask cleaning method according to another aspect of the disclosure may further include operation S15A of pre-treating the mask.

Operation S15A of pre-treating the mask may be performed before operation S20A of controlling the heating unit such that the heating temperature value is equal to the first process temperature value is performed. In operation S15A of pre-treating the mask, the organic material on the mask M may be pre-treated by controlling the heating unit 200 before cleaning of the mask M.

In operation S15A of pre-treating the mask, the mask cleaning device 10 may be controlled such that the mask M has a temperature value corresponding to the second process temperature value. In operation S15A of pre-treating the mask, the heating unit 200 and the gas supply unit 400 may be controlled simultaneously or separately such that the mask M has a temperature value corresponding to the second process temperature value.

In an aspect, in operation S15A of pre-treating the mask, the heating unit 200 may be controlled such that the heating temperature value is equal to the second process temperature value.

In operation S15A of pre-treating the mask, the heating unit 200 may be controlled such that the heating temperature value of the main body 210 has the second process temperature value. In operation S15A of pre-treating the mask, the heating temperature value may be adjusted such that the mask M arranged on the main body 210 has a temperature value corresponding to the second process temperature value.

In another aspect, in operation S15A of pre-treating the mask, an inert gas having a temperature value corresponding to the second process temperature value may be supplied into the chamber 100 using the gas supply unit 400. In operation S15A of pre-treating the mask, the temperature of the mask M arranged inside the chamber 100 may be controlled by supplying the inert gas having the temperature value corresponding to the second process temperature value into the chamber 100. Thus, in operation S15A of pre-treating the mask, the mask M may be pre-treated.

In another aspect, in operation S15A of pre-treating the mask, the heating unit 200 and the gas supply unit 400 may be simultaneously controlled such that the mask M has the temperature value corresponding to the second process temperature value. In operation S15A of pre-treating the mask, the main body 210 may be controlled to have the second process temperature value, and at the same time, the inert gas having the temperature value corresponding to the second process temperature value may be supplied into the chamber 100 from the gas supply unit 400. Thus, pre-treatment of the organic material arranged on the mask M may be performed quickly.

In an aspect, the first process temperature value may be greater than the second process temperature value. In operation S20A of controlling the heating unit such that the heating temperature value is equal to the first process temperature value, the heating temperature value of the main body 210 may be greater than the heating temperature value of the main body 210 in operation S20A of controlling the heating unit such that the heating temperature value is equal to the second process temperature value.

As the second process temperature value is lower than the first process temperature value, the hardness of the organic material on the mask M may not be high. In case that the heating temperature value is high during the pre-treatment process, the organic material on the mask M may be hardened depending on the pre-treatment. Therefore, by setting the second process temperature value lower than the first process temperature value, the hardness of the organic material attached to the mask M after pre-treatment may be maintained low. By setting the second process temperature value lower than the first process temperature value, the organic material may be caused to smoothly react with the cleaning gas CG during cleaning of the mask M. Thus, in operation S30A of cleaning the mask, the cleaning efficiency of the mask M may be improved.

In operation S15A of pre-treating the mask, the heating unit 200 may be controlled during the pre-treatment time. In operation S15A of pre-treating the mask, the heating temperature value of the main body 210 may be adjusted during the pre-treatment time such that the organic material on the mask M has a temperature value corresponding to the second process temperature value during the pre-treatment time. Thus, in operation S15A of pre-treating the mask, the organic material may be pre-treated for a sufficient time.

In an aspect, the pre-treatment time may be less than the cleaning time. In case that the pre-treatment time is less than the cleaning time, the hardness of the organic material attached to the mask M may be low after operation S15A of pre-treating the mask is performed. In case that the pre-treatment time is less than the cleaning time, the process time for cleaning the mask M may be shortened in operation S30A of cleaning the mask.

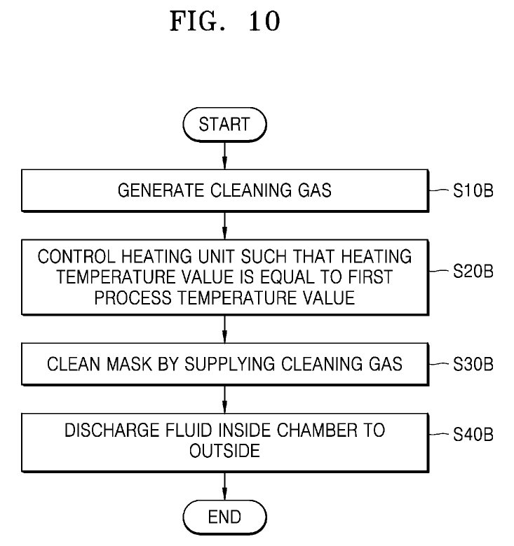

FIG. 10 is a flowchart showing a mask cleaning method according to another aspect of the disclosure.

A mask cleaning method according to another aspect of the disclosure differs from the mask cleaning method according to an aspect of the disclosure in that the mask cleaning method includes operation S40B of discharging fluid inside a chamber to the outside, and therefore, differences will be mainly described.

Referring to FIG. 10, the mask cleaning method according to another aspect of the disclosure may further include operation S40B of discharging the fluid inside the chamber to the outside.

In operation S40B of discharging the fluid inside the chamber to the outside, the fluid inside the chamber 100 may be discharged using the pump 500. In operation S40B of discharging the fluid inside the chamber to the outside, the pump 500 may operate to discharge the cleaning gas CG and the inert gas, contained inside the chamber 100, to the outside.

In operation S40B of discharging the fluid inside the chamber to the outside, the pressure inside the chamber 100 may be adjusted. In operation S40B of discharging the fluid inside the chamber to the outside, the pressure applied to the mask M may be adjusted by determining the amount of fluid contained inside the chamber 100.

In operation S40B of discharging the fluid inside the chamber to the outside, the pressure inside the chamber 100 may be maintained constant. In operation S40B of discharging the fluid inside the chamber to the outside, fluid of an amount corresponding to the amount of fluid supplied into the chamber 100 from the cleaning gas supply unit 300 and the gas supply unit 400 may be withdrawn from the chamber 100. Thus, cleaning of the mask M may be stably performed inside the chamber 100.

In operation S40B of discharging the fluid inside the chamber to the outside, the pressure inside the chamber 100 may be maintained low. In operation S40B of discharging the fluid inside the chamber to the outside, the amount of fluid contained inside the chamber 100 may be kept small to minimize the amount of cleaning gas CG remaining around the mask M. In operation S40B of discharging the fluid inside the chamber to the outside, the cleaning gas CG reacting with the organic material on the mask M may be quickly discharged to outside the chamber 100. Thus, the amount of foreign substances remaining on the mask M in cleaning of the mask M may be minimized.

In an aspect, operation S40B of discharging the fluid inside the chamber to the outside may be performed simultaneously with operation S30B of cleaning the mask. In operation S40B of discharging the fluid inside the chamber to the outside, the cleaning gas CG may be supplied from the cleaning gas supply unit 300 and at the same time, the fluid inside the chamber 100 may be discharged to the outside. Thus, the pressure inside the chamber 100 may be maintained constant in operation S30B of cleaning the mask.

The mask cleaning method according to aspects of the disclosure may maximize the cleaning efficiency of the mask by adjusting the temperature of the mask. The mask cleaning method according to aspects of the disclosure may improve the cleaning efficiency of the mask by adjusting the temperature of the heating unit where the mask is arranged during the mask cleaning process, and may maximize the cleaning efficiency of the mask by pre-treating organic material on the mask before the mask cleaning process. The mask cleaning method according to aspects of the disclosure may maximize cleaning efficiency by generating cleaning gas in a space separate from the cleaning space of the mask and controlling the pressure within the cleaning space.

A mask cleaning device and a mask cleaning method according to an aspect of the disclosure may maximize the cleaning efficiency of the mask by adjusting the temperature of the mask. The mask cleaning device and mask cleaning method according to aspects of the disclosure may improve the cleaning efficiency of the mask by adjusting the temperature of the heating unit where the mask is arranged during the mask cleaning process, and may maximize the cleaning efficiency of the mask by pre-treating organic material on the mask before the mask cleaning process. The mask cleaning device and mask cleaning method according to aspects of the disclosure may maximize the cleaning efficiency by generating a cleaning gas in a space separate from the cleaning space of the mask and adjusting the pressure in the cleaning space.

Each of the aspects described above may be implemented independently, but it goes without saying that the structure of each aspect may be applied in combination to other aspects.

Although the disclosure has been described with reference to an aspect shown in the drawings, it will be understood by those of ordinary skill in the art that various modifications and equivalent other aspects may be made from the shown aspect. Accordingly, the true technical scope of the disclosure should be defined by the technical spirit of the appended claims.

Specific implementations described in the aspects are examples and do not limit the scope of the aspects in any way. Unless there is specific mentioning, such as "essential" or "important", it may not be a necessary component for the application of the disclosure.

In the specification (especially, claims) of the disclosure, the use of the term "the" and similar indicators thereof may correspond to both the singular and the plural. In addition, in case that the range is described in the aspects, the range includes the disclosure to which an individual value falling within the range is applied (unless stated otherwise), and is the same as the description of an individual value constituting the range in the description of the disclosure. Finally, unless there is an apparent description of the order of operations constituting the method according to aspects or a contrary description thereof, the operations may be performed in an appropriate order. The aspects are not necessarily limited to the order in which the above steps are described. The use of all examples or exemplary terms in the present disclosure are to simply describe the aspects in detail, and unless the range of the aspects is not limited by the examples or the exemplary terms unless limited by the claims. In addition, it may be understood by those of ordinary skill in the art that various modifications, combinations, and changes may be made according to design conditions and factors within the scope of the appended claims or equivalents thereof.

What is claimed is:

1. A mask cleaning device comprising:
a chamber comprising a cleaning space for a mask;
a heating unit comprising a main body, wherein the mask is seated on the main body, and wherein the heating unit is configured to adjust a heating temperature value of the main body;
a cleaning gas supply unit configured to supply a cleaning gas to the mask; and
a control unit configured to control the heating unit and the cleaning gas supply unit,
wherein the control unit is configured to control the heating unit such that the heating temperature value of the main body is equal to or greater than a first process temperature value, and wherein the control unit is configured to control the cleaning gas supply unit to supply the cleaning gas to the mask during a cleaning time.

2. The mask cleaning device of claim 1, wherein the control unit is further configured to control the heating unit such that the heating temperature value is equal to or greater than a second process temperature value during a pre- treatment time, wherein the pre-treatment time is before the cleaning time.

3. The mask cleaning device of claim 2, wherein the first process temperature value is greater than the second process temperature value.

4. The mask cleaning device of claim 2, wherein a duration of the pre-treatment time is less than a duration of the cleaning time.

5. The mask cleaning device of claim 1, further comprising a gas supply unit configured to supply an inert gas into the chamber.

6. The mask cleaning device of claim 1, wherein the cleaning gas supply unit comprises:
a cleaning gas generation unit comprising an inner space separated from the chamber, wherein the cleaning gas generation unit is configured to generate the cleaning gas using a source gas; anda spray unit fluidly connected to the cleaning gas generation unit, wherein the spray unit is configured to spray the cleaning gas generated in the cleaning gas generation unit to the mask.

7. The mask cleaning device of claim 6, wherein the spray unit faces a surface of the main body of the heating unit on which the mask is seated.

8. The mask cleaning device of claim 1, wherein the cleaning gas comprises hydrogen radicals.

9. The mask cleaning device of claim 8, wherein the cleaning gas supply unit is configured to generate the cleaning gas comprising the hydrogen radicals by combining hydrogen gas and water vapor.

10. The mask cleaning device of claim 1, wherein the heating unit comprises an elevating unit configured to move the mask apart from the main body.

11. The mask cleaning device of claim 10, wherein the control unit is configured to control the elevating unit such that the mask is moved apart from the main body after a first time period, and the mask is returned to the main body after a second time period.

12. The mask cleaning device of claim 1, further comprising a pump configured to discharge fluid from the chamber to an area outside the chamber.

13. (canceled)

14. A mask cleaning method comprising:
generating a cleaning gas using a source gas;
adjusting a heating temperature value of a main body on which a mask is seated such that the heating temperature value has a first process temperature value; and
supplying a cleaning gas to the mask during a cleaning time to clean the mask, wherein the mask and the main body are within a chamber.

15. The mask cleaning method of claim 14, further comprising pre-treating the mask such that the mask has a temperature value corresponding to a second process temperature value during a pre-treatment time.

16. The mask cleaning method of claim 15, wherein the first process temperature value is greater than the second process temperature value.

17. The mask cleaning method of claim 15, wherein a duration of the pre-treatment time is less than a duration of the cleaning time.

18. The mask cleaning method of claim 14, wherein the cleaning gas comprises hydrogen radicals.

19. The mask cleaning method of claim 14, wherein the cleaning of the mask comprises:
separating the mask from the main body after a first time period, while supplying the cleaning gas; and
seating the mask onto the main body after a second time period, while supplying the cleaning gas.

20. The mask cleaning method of claim 14, further comprising discharging a fluid from the chamber to an area outside the chamber.

21. An electronic device manufacturing system comprising:
a cleaning device configured to remove an organic material from a mask;
a deposition device configured to manufacture a display panel using the mask from which the organic material is removed; and
an assembly device configured to assemble an electronic device using the display panel,
wherein the cleaning device comprises:
a chamber comprising a cleaning space for the mask;
a heating unit comprising a main body, wherein the mask is seated on the main body, and wherein the heating unit is configured to adjust a heating temperature value of the main body;
a cleaning gas supply unit configured to supply a cleaning gas to the mask; and
a control unit configured to control the heating unit and the cleaning gas supply unit,
wherein the control unit is configured to control the heating unit such that the heating temperature value of the main body is equal to or greater than a first process temperature value, and wherein the control unit is configured to control the cleaning gas supply unit to supply the cleaning gas to the mask during a cleaning time.
